(19) United States
(12) Patent Application Publication
(10) Pub. No.: US 2013/0240932 A1
(43) Pub. Date: Sep. 19, 2013

(54) SEMICONDUCTOR LIGHT-EMITTING DEVICE AND MANUFACTURING METHOD THEREOF

(71) Applicants: Sheng-Han Tu, Tainan City (TW); Gwo-Jiun Sheu, Tainan City (TW); Sheng-Chieh Tsai, Tainan City (TW); Kuan-Yung Liao, Tainan City (TW); Yun-Li Li, Tainan City (TW)

(72) Inventors: Sheng-Han Tu, Tainan City (TW); Gwo-Jiun Sheu, Tainan City (TW); Sheng-Chieh Tsai, Tainan City (TW); Kuan-Yung Liao, Tainan City (TW); Yun-Li Li, Tainan City (TW)

(73) Assignee: Genesis Photonics Inc., Tainan City (TW)

(21) Appl. No.: 13/798,149

(22) Filed: Mar. 13, 2013

(30) Foreign Application Priority Data
Mar. 14, 2012 (TW) 101108663

(51) Int. Cl. H01L 33/58

(52) U.S. Cl. CPC H01L 33/58
USPC 257/98; 438/29

(57) ABSTRACT

A semiconductor light-emitting device and a manufacturing method thereof are provided, wherein the semiconductor light-emitting device includes a substrate, a first type doped semiconductor layer, a light-emitting layer, a second type doped semiconductor layer and an optical micro-structure layer. The first type doped semiconductor layer is disposed on the substrate and includes a base portion and a mesa portion. The base portion has a top surface, and the mesa portion is disposed on the top surface of the base portion. The light-emitting layer is disposed on the first type doped semiconductor layer. The second type doped semiconductor layer is disposed on the light-emitting layer. The optical micro-structure layer is embedded in the first type doped semiconductor layer.

### CROSS-REFERENCE TO RELATED APPLICATION

This application claims the priority benefit of Taiwan application serial no. 101108663, filed on Mar. 14, 2012. The entirety of the above-mentioned patent application is hereby incorporated by reference herein and made a part of this specification.

### BACKGROUND

1. Field of the Invention

The invention relates to a light-emitting device and a manufacturing method thereof In particular, the invention relates to a semiconductor light-emitting device and a manufacturing method thereof

2. Description of Related Art

The manufacturing and application of light-emitting diode (LED) has gradually matured along with the advances in optical-electronic technologies. Light-emitting diode (LED) has the advantages of less pollution, low power consumption, short response time and long lifetime, so that it has been widely applied in various fields of light sources or illumination such as traffic lights, outdoor billboards and backlight sources of displays. As a result, light-emitting diode (LED) has gradually become one of the most eye-catching optical-electronic industries.

Generally, the depositions of electrodes of a light-emitting diode can be categorized into horizontal deposition and vertical deposition, wherein the horizontal deposition refers to disposing the first and second electrodes on the same side of the epitaxial structure of the light-emitting diode while the vertical deposition refers to disposing the first and second electrodes respectively on the two opposite sides of the epitaxial structure of the light-emitting diode. Specifically, in the light-emitting diode structure where the electrodes are disposed horizontally and in the conventional manufacturing method of the light-emitting diode, a first type doped semiconductor layer, for example, N-type semiconductor layer, is formed on a substrate, and followed by a light-emitting layer and a second type doped semiconductor layer, for example, P-type semiconductor layer. Next, parts of the N-type semiconductor layer, light-emitting layer and the second type doped semiconductor layer are removed by etching in a vertical direction, and a first electrode and a second electrode are respectively disposed on the N-type semiconductor layer and the P-type semiconductor layer. A current flows to the N-type semiconductor from the P-type semiconductor. The current is over-concentrated in a small region between the two electrodes, which not only results in the non-uniformity of the light emitted, but is also easy to lead to the damages of the light-emitting diode or light-emitting efficiency decreased of the light-emitting diode out of poor heat dissipation because of the over-concentration of the heat generated through the flow of the current. In addition, provided that the surface removed by etching in the vertical direction is a vertical surface, which easily results in the decreases of the light extraction efficiency of the light emitted by the light-emitting diode due to total reflection within the semiconductor light-emitting device.

### SUMMARY OF THE INVENTION

The invention provides a semiconductor light-emitting device and a manufacturing method thereof, and the semiconductor light-emitting device has a high light extraction efficiency.

An embodiment of the invention provides a semiconductor light-emitting device, which includes a substrate, a first type doped semiconductor layer, a light-emitting layer, a second type doped semiconductor layer and an optical micro-structure layer. The first type doped semiconductor layer is disposed on the substrate and includes a base portion and a mesa portion. The base portion has an upper surface and the mesa portion is disposed on the upper surface of the base portion. The light-emitting layer is disposed on the first type doped semiconductor layer. The second type doped semiconductor layer is disposed on the light-emitting layer. The optical micro-structure layer is embedded in the first type doped semiconductor layer.

Another embodiment of the invention provides a method for manufacturing a semiconductor light-emitting device, which includes the following steps. A substrate is provided. A first type doped semiconductor material is grown on the substrate to form a base portion of a first type doped semiconductor. A patterned growth barrier layer is formed on the base portion of the first type doped semiconductor, so that the patterned growth barrier layer covers a second portion of the first type doped semiconductor and exposes the first portion of the first type doped semiconductor. The first type doped semiconductor material is proceeded to be grown on the first portion to form a mesa portion of the first type doped semiconductor. A light-emitting layer is formed on the mesa portion of the first type doped semiconductor. A second type doped semiconductor is formed on the light-emitting layer.

Based on the above, the embodiments of the invention improve light extraction efficiency by changing the shape and structure of the first type doped semiconductor layer, for example, providing a tilting mesa portion of the first type doped semiconductor layer to reduce the probability of the light emitted from the light-emitting diode to be totally reflected within the semiconductor light-emitting structure happening, which leads to a low light extraction efficiency. Alternatively, the embodiments of the invention provide an optical micro-structure layer embedded in the mesa portion to change light-emitting characteristics. In the embodiments of the invention, part of the growth of the first type doped semiconductor material is barricaded by the patterned growth barrier layer formed on the base portion of the first type doped semiconductor, and thus the mesa portion of the first type doped semiconductor, the light-emitting layer and the second type doped semiconductor layer can be formed directly in part of the region without growing the first type doped semiconductor layer over the whole surface and using the etching method to form the mesa portion of the first type doped semiconductor. As a result, the stress of the mesa portion of the first type doped semiconductor, the light-emitting layer and the second type doped semiconductor layer can be effectively reduced, and the epitaxial quality of the mesa portion of the first type doped semiconductor, the light-emitting layer and the second type doped semiconductor layer can be further improved.

In order to make the aforementioned features and strengths of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIGS. 1A through 1F are schematic cross-sectional views illustrating a process of manufacturing a semiconductor light-emitting device according to one embodiment of the invention.

FIG. 2 is a schematic top view of a light-emitting device according to one embodiment of the invention.

FIGS. 3 through 6 are schematic top views of the varieties of the optical micro-structure layer of FIG. 1F.

FIG. 7 is a schematic cross-sectional view illustrating a semiconductor light-emitting device according to one embodiment of the invention.

FIG. 8 is a schematic cross-sectional view illustrating a semiconductor light-emitting device according to another embodiment of the invention.

FIG. 9 is a schematic top view illustrating another variety of the optical micro-structure layer of FIG. 1F.

FIG. 10 is a schematic top view illustrating other varieties of the optical micro-structure layer of FIG. 1F.

FIG. 11 is a schematic cross-sectional view illustrating a semiconductor light-emitting device according to another embodiment of the invention.

### DESCRIPTION OF EMBODIMENTS

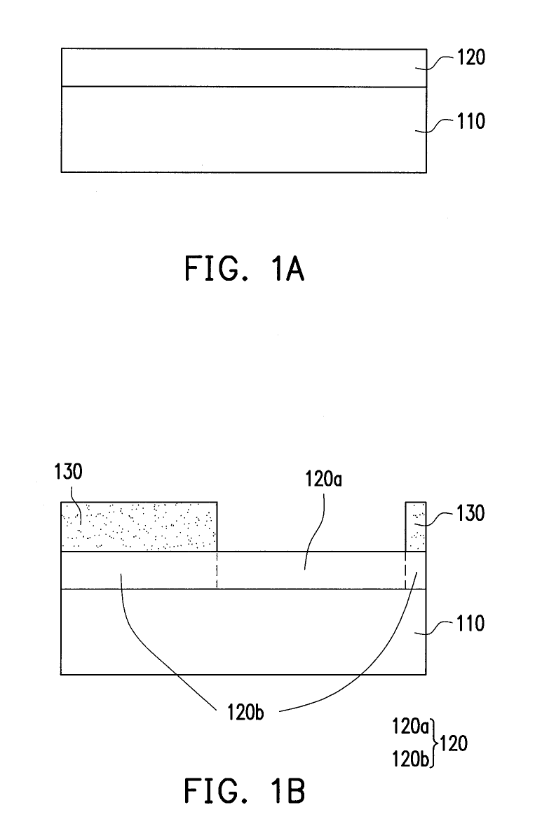

FIGS. 1A through 1F are schematic cross-sectional views illustrating a process flow of manufacturing a semiconductor light-emitting device according to one embodiment of the invention.

Please refer to FIG. 1A first. First, a first type doped semiconductor material is grown on a substrate 110 to form a base portion of a first type doped semiconductor 120, wherein the substrate 110 is, for example, a silicon substrate, a copper substrate, a silicon carbide (SiC) substrate or a sapphire substrate while the first type doped semiconductor material is, for example, N-type gallium nitride (GaN).

Please refer to FIG. 1B. A patterned growth barrier layer 130 is formed on the base portion of the first type doped semiconductor 120 after the base portion of the first type doped semiconductor 120 is formed, so that the patterned growth barrier layer 130 covers a second portion 120b of the base portion of the first type doped semiconductor 120 and exposes the first portion 120a of the base portion of the first type doped semiconductor 120, wherein the patterned growth barrier layer 130 is made of silicon dioxide (SiO₂) or aluminum nitride (AlN), for example.

Please refer to FIG. 1C. In this embodiment, an optical micro-structure layer 140 can be formed on the first portion 120a after the patterned growth barrier layer 130 is grown, wherein the optical micro-structure layer 140 can be formed by being exposed and etched and the material thereof may be the material not cracking under high temperatures such as silicon dioxide (SiO₂) or aluminum nitride (AlN). In other embodiments, it could be that no optical micro-structure layer 140 is formed on the first portion 120a. Moreover, in this embodiment, the optical micro-structure layer 140 can include a plurality of discontinuous optical micro-structures 141. In addition, the optical micro-structures 141 can include a phosphor 142. The phosphor will emit a light with a longer wavelength after being excited by the light with a shorter wavelength, wherein the color of the fluorescent light emitted from the phosphor after being excited is, for example, red, green or blue.

Please refer to FIG. 1D. The first type doped semiconductor material is proceeded to be grown on the first portion 120a after the optical micro-structure layer 140 is grown to form a mesa portion of the first type doped semiconductor 121, wherein the optical micro-structure layer 140 is embedded between the mesa portion of the first type doped semiconductor 121 and the first portion 120a. Accordingly, the mesa portion of the first type doped semiconductor 121 and the base portion of the first type doped semiconductor 120 together form a first type doped semiconductor layer 122. In addition, the mesa portion of the first type doped semiconductor 121 has a top surface S1 and a side-wall surface S2, and the side-wall surface S2 connects the top surface S1 and the upper surface S3 of the base portion of the first type doped semiconductor 120, wherein the side-wall surface S2 tilts relative to the upper surface S3. In this embodiment, the angle θ of the side-wall surface S2 tilting relative to the upper surface S3 is, for example, greater than 0° and less than 90°, that is, the cross section of the mesa portion of the first type doped semiconductor 121 is trapezoid-shaped. However, in other embodiments, the angle θ between the side-wall surface S2 and upper surface S3 may be substantially 90°.

In addition, it is worth noting that the mesa portion of the first type doped semiconductor 121 of the first type doped semiconductor layer 122 is grown after the optical micro-structure layer 140 is grown on the first portion 120a and the stress on the first type doped semiconductor material can be reduced due to the second growth effects of the epitaxial lateral overgrowth (ELOG). As a result, the light-emitting efficiency is further improved because of lower probability of stacking defaults or dislocation occurring in this embodiment.

And then, please refer to FIG. 1E. A light-emitting layer 150 is formed on the first type doped semiconductor layer 122, and a second type doped semiconductor layer 160 is formed on the light-emitting layer 150, wherein the light-emitting layer 150 is, for example, a quantum well layer or a multiple quantum well (MQW) layer while the second type doped semiconductor layer 160 is made of P-type gallium nitride, for example. In another embodiment, the first type doped semiconductor material may be P-type gallium nitride while the second type doped semiconductor layer 160 may be made of N-type gallium nitride.

It is to be noted that the side-wall surface S2 tilts relative to the upper surface S3, and thus when the light emitted from the light-emitting layer 150 irradiating the side-wall surface S2, it has an incident angle less than a critical angle and directly passes through and exits the side-wall surface S2. More particularly, the embodiment may solve the problem of low light extraction efficiency because of total reflection by changing the tilting angle θ of the side-wall surface S2 relative to the upper surface S3.

And then, please refer to FIG. 1F. The patterned growth barrier layer 130 is removed after the light-emitting layer 150 and the second type doped semiconductor layer 160 are formed, and a first electrode 170 and a second electrode 180 are formed on the second portion 120b and the second type doped semiconductor layer 160, respectively. The first electrode 170 and the second electrode 180 are made of a single conductive material layer or conductive materials stacked in multiple layers, wherein the conductive material is, for example, gold, titanium, aluminum, chromium, platinum, other conductive materials, or any combination thereof. In addition, a material with high conductivity or Ohmic-contact characteristic can be further included between the electrodes and the semiconductor layers in one embodiment of the invention. The first electrode 170 and the second electrode 180 may be respectively electrically connected to the second portion 120b of the first type doped semiconductor layer 122 and the second type doped semiconductor layer 160 through materials with high conductivity or Ohmic-contact characteristic in one embodiment, however, the invention is not limited thereto. The semiconductor light-emitting device 100 is completed through the above steps. The semiconductor light-emitting device 100 includes a substrate 110, a first type doped semiconductor layer 122 (including the mesa portion of the first type doped semiconductor 121 and the base portion of the first type doped semiconductor 120), an optical micro-structure layer 140, a light-emitting layer 150 and a second type doped semiconductor layer 160. In this embodiment, the semiconductor light-emitting device 100 may further include the first electrode 170 and the second electrode 180.

It is worth noting that the patterned growth barrier layer 130 is formed on the base portion of the first type doped semiconductor 120 (the location reserved for the first electrode 170), and thus the stress on the semiconductor light-emitting structure 100 according to the embodiment of the invention is less than that in the conventional art, in which a first type doped semiconductor is grown on the whole surface of the substrate with a larger area.

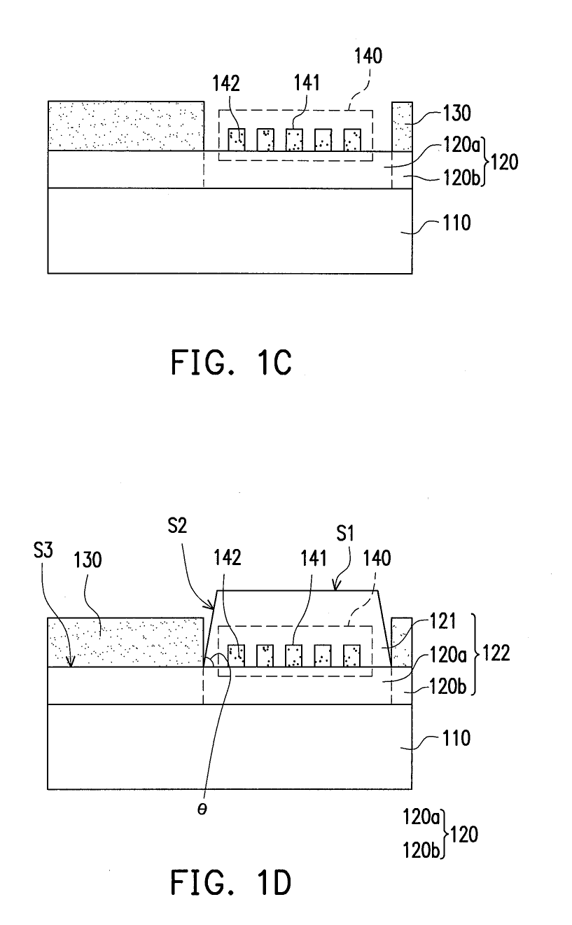

FIG. 2 is a top view of the semiconductor light-emitting device according to an embodiment of the invention and FIG. 1F is a schematic cross-sectional view along line A-A′ of FIG. 2. As shown in FIG. 2, the first electrode 170 is disposed on the second portion 120b. The mesa portion of the first type doped semiconductor 121, the light-emitting layer 150, the second type doped semiconductor layer 160 and the second electrode 180 are disposed in sequence from bottom to top.

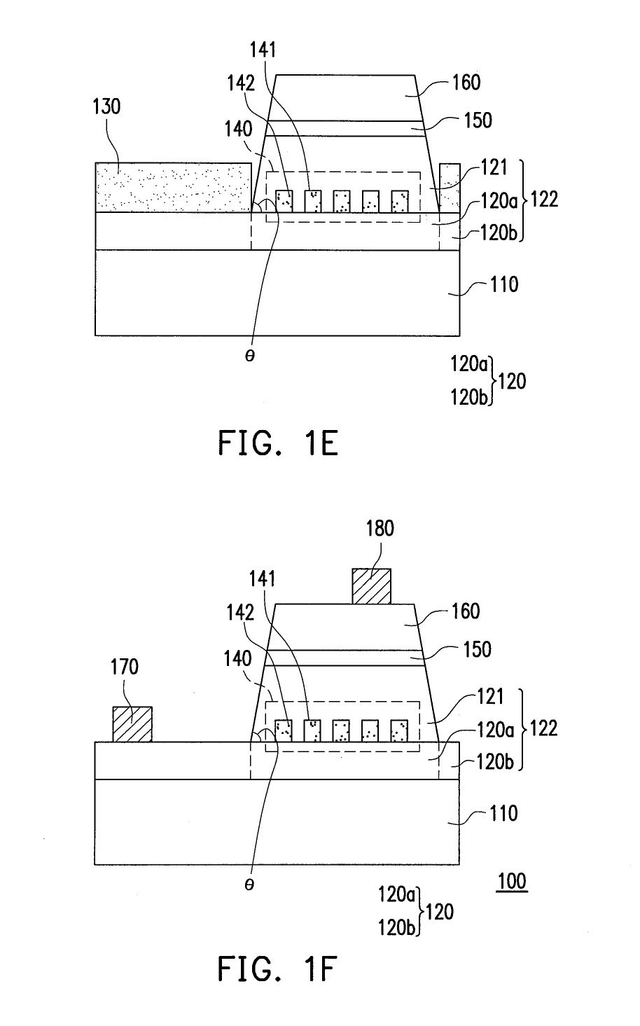

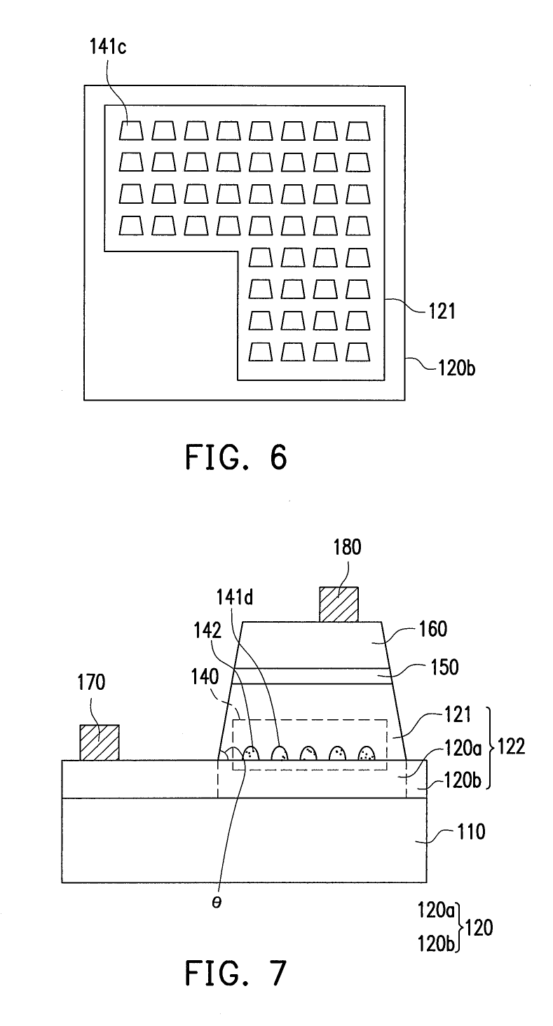

FIG. 3 through FIG. 9 are schematic top views illustrating various variations of the optical micro-structure layer of FIG. 1F. In order to make the figures easier to be understood by readers, other film layers above the mesa portion of the first type doped semiconductor 121 of the semiconductor light-emitting device 100 are omitted from FIG. 3 through FIG. 9, in that way, readers can directly see the optical micro-structure layer 140 below the mesa portion of the first type doped semiconductor 121. The structure and the shape of the optical micro-structure layer 140 can vary as the following, such as those illustrated in FIG. 3 through FIG. 9.

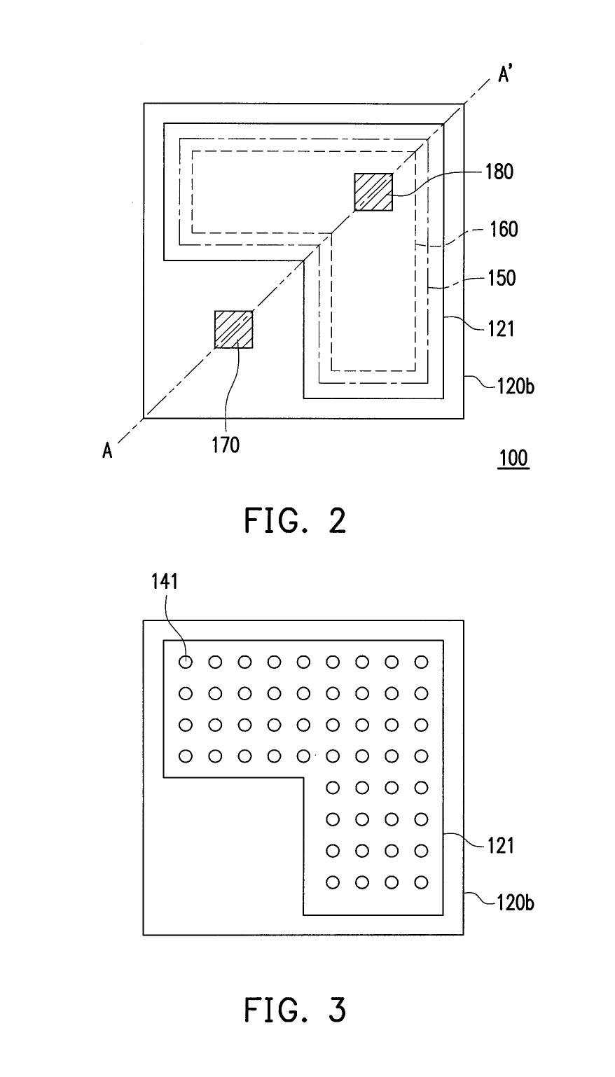

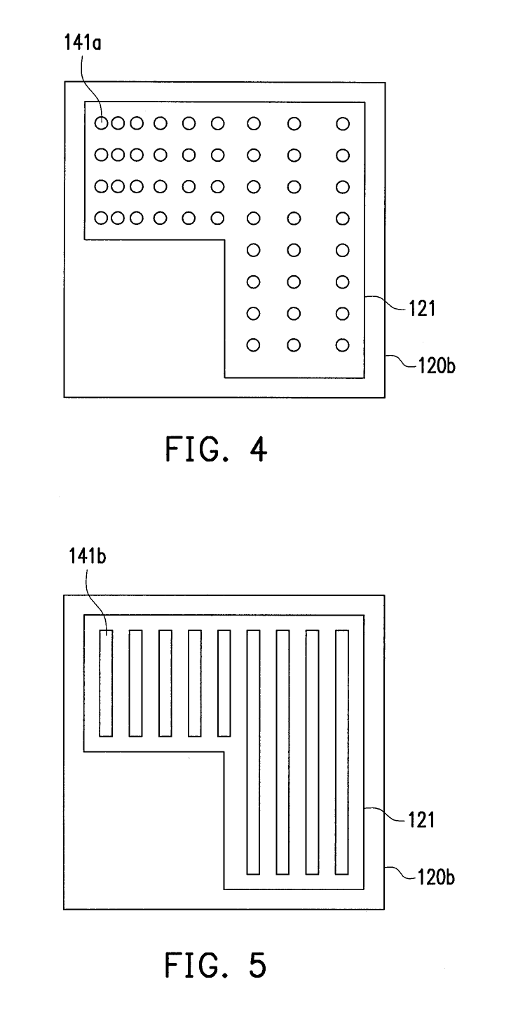

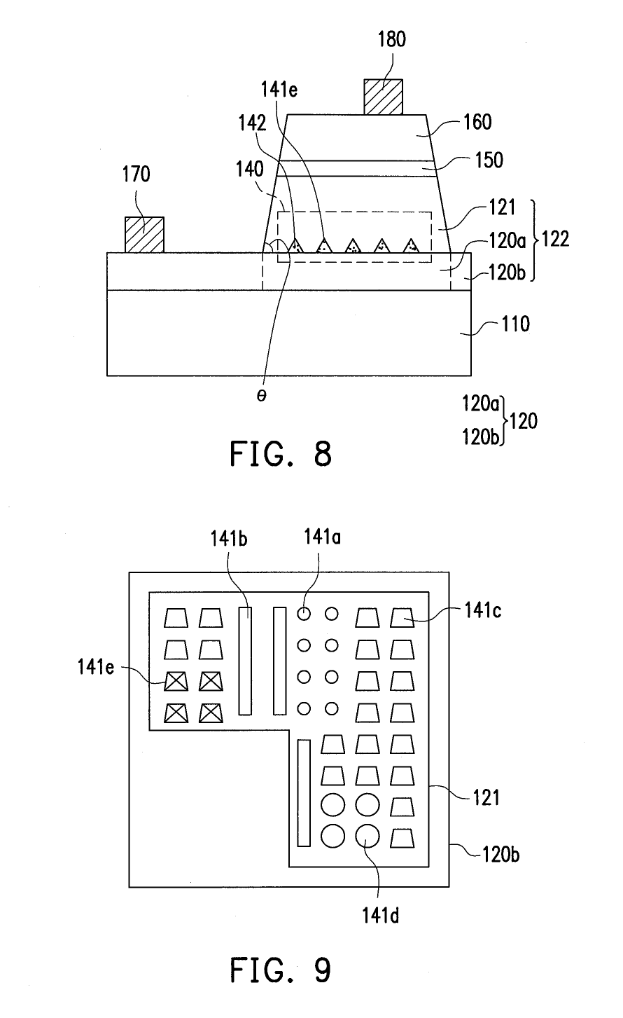

To be specific, FIG. 3 is the top view of FIG. 1F. Please refer to FIG. 3, the optical micro-structure layer 140 is constituted by, for example, optical micro-structures 141 shaped as columns, while the arrangement of the optical micro-structures 141 are, for example, substantially uniformly distributed, wherein the cross sectional view of the optical micro-structures 141 can be referred to FIG. 1F. Please refer to FIG. 4. In another embodiment, the surface number densities of at least a part of the optical micro-structures 141a of the optical micro-structure layer 140 vary according to different locations, for example, the density distribution of the optical micro-structures 141 a becomes lower from one side to the opposite side in the optical micro-structure layer 140 in a gradual manner. Please refer to FIG. 5. The optical micro-structures 141b are shaped as, for example, bars. Please refer to FIG. 6. The optical micro-structures 141c are shaped as, for example, islands. FIG. 7 is a schematic cross-sectional view of the semiconductor light-emitting device according to one embodiment of the invention. Please refer to FIG. 7. The optical micro-structures 141d are shaped as, for example, dots and the top view thereof are similar to FIG. 3. While in another embodiment, the distribution of the optical micro-structures 141d is, for example, as shown in FIG. 4. In the optical micro-structure layer 140, the density distribution of the optical micro-structures 141d becomes lower from one side to the opposite side in a gradual manner. FIG. 8 is a schematic cross-sectional view of the semiconductor light-emitting device according to another embodiment of the invention. Please refer to FIG. 8. The optical micro-structures 141e are shaped as, for example, cones or polygonal pyramids and the top view thereof are similar to FIG. 3. While in another embodiment, the distribution of the optical micro-structures 141e is, for example, as shown in FIG. 4. In the optical micro-structure layer 140, the density distribution of the optical micro-structures 141 e becomes lower from one side to the opposite side in a gradual manner. Alternatively, the optical micro-structure layer can include any combination of optical micro-structures 141a, 141b, 141c, 141d and 141e. Random scattering light can be increased or desired light shape can be outputted by adjusting the structures or densities of different optical micro-structures. Furthermore, the optical micro-structure layer 140 can also be optical micro-structures 141f in a continuous manner as shown in FIG. 10. Also, the locations of different optical micro-structures can be adjusted to vary the path of the current. In that way, the deficiencies of poor heat dissipation, damages to the semiconductor light-emitting structures and lowered light-emitting efficiency can be improved. The deficiencies are resulted from non-uniformity of the light emitted and over-concentration of heat due to the over-concentration of current in a small region between two electrodes in the conventional art.

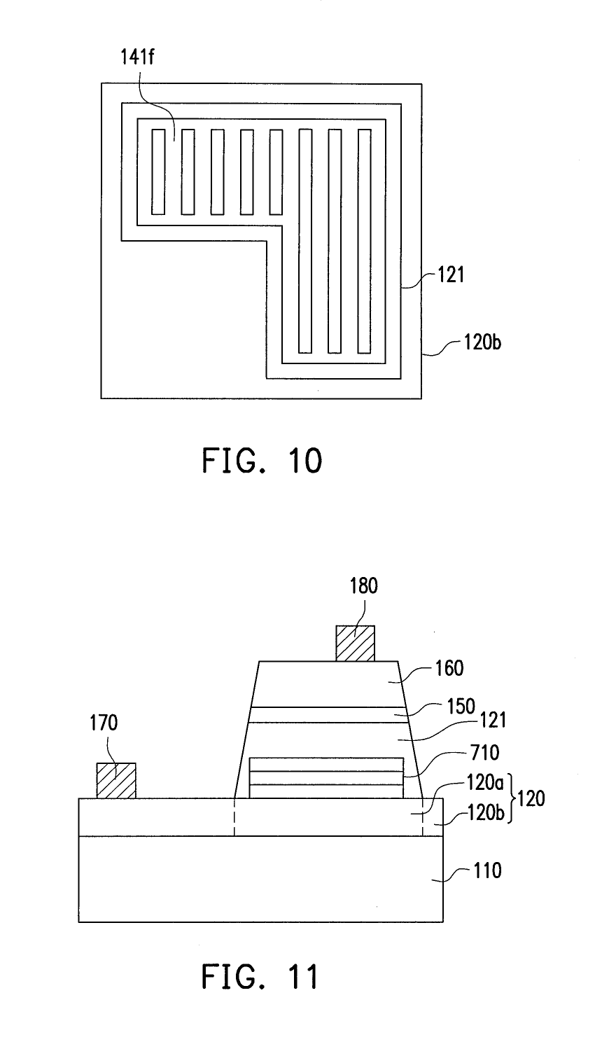

Other than that, as shown in FIG. 11, the optical micro-structure layer 140 can be replaced with a distributed Bragg reflector (DBR) layer 710 in another embodiment, wherein the DBR layer 710 is a multi-layer structure that can increase reflectivity. The materials of the DBR layer 710 include one or more high-refractivity materials and one or more low-refractivity materials, which are stacked by the optical coating manner. The high-refractivity materials are, for example, Ta₂O₅, TiO₂, Ti₃O₅ or Nb₂O₅ while low-refractivity materials are, for example, SiO₂ or MgF₂. In other embodiments, the optical micro-structure layer 140 can also be the combination of optical micro-structures 141 and the DBR layer 710.

It is worth noting that the current techniques of white light light-emitting diode mainly use blue light light-emitting diode chips accompanied by a phosphor that emits yellow light, and the red light waveband has weaker light intensity, and thus the light displayed is in rather cold tone. In one embodiment of the invention, a phosphor that emits red light can be added in the optical micro-structure layer 140 to improve the light intensity of the red light waveband and further improve the color rendering index of the semiconductor light-emitting structure 100. For example, phosphors that emit yellow and red lights are added in the optical micro-structure layer 140 and the blue light emitted from the light-emitting layer 150 of the semiconductor structure 100 is used to excite the yellow phosphor, wherein the blue light and yellow light can be blended into a white light while the red light excited by blue light through red phosphor can improve the light intensity of the red light waveband, so as to improve color rendering index. In addition, the light-emitting layer 150 can be designed to emit ultraviolet light while the phosphors can include red, green and blue phosphors, such that the ultraviolet light can excite red light, green light and blue light and these lights can be blended into a white light in another embodiment.

In summary of the above, the semiconductor light-emitting structure and the manufacturing thereof in the embodiments relate to providing tilting angle to the mesa portion of a first type doped semiconductor, to solve the problem of low light extraction efficiency resulted from the full reflection of a vertical surface in the conventional art. In addition, the stress on the semiconductor light-emitting structure is reduced by the patterned growth barrier layer in manufacturing processes. Further, light-emitting efficiency is improved by reducing the probability of stacking defaults or dislocation happening in the epitaxy process by the optical-micro structures. Moreover, the color rendering index of the light outputted is improved by adding at least one phosphor in the semiconductor light-emitting structure, or the light extraction efficiency is improved by using DBR layer to increase reflectivity and random scattering light. What is more, the embodiment of the invention can increase random scattering light, generate the desired light shape to be outputted and improve the deficiencies such as non-uniformity of emitted light, poor heat dissipation and damages to the semiconductor light-emitting structure by adjusting the shape, density or location of different optical micro-structures.

It will be apparent to those skilled in the art that various modifications and variations can be made to the structure of the invention without departing from the scope or spirit of the invention. In view of the foregoing, it is intended that the present invention cover modifications and variations of this invention provided they fall within the scope of the following claims and their equivalents.

What is claimed is:

1. A semiconductor light-emitting device, comprising:
a substrate;
a first type doped semiconductor layer disposed on the substrate and comprising a base portion and a mesa portion, wherein the base portion has an upper surface and the mesa portion is disposed on the upper surface of the base portion;
a light-emitting layer disposed on the first type doped semiconductor layer;
a second type doped semiconductor layer disposed on the light-emitting layer; and
an optical micro-structure layer embedded in the first type doped semiconductor layer.

2. The semiconductor light-emitting device according to claim 1, wherein the mesa portion has a top surface and a side-wall surface.

3. The semiconductor light-emitting device according to claim 2, wherein the side-wall surface connects the top surface and the upper surface of the base portion.

4. The semiconductor light-emitting device according to claim 3, wherein the side-wall surface has a tilting angle relative to the upper surface of the base portion, and the tilting angle is greater than 0° and less than 90°.

5. The semiconductor light-emitting device according to claim 1, wherein the cross section of the mesa portion is trapezoid-shaped.

6. The semiconductor light-emitting device according to claim 1, wherein the light-emitting layer is disposed on the mesa portion.

7. The semiconductor light-emitting device according to claim 1, wherein the optical micro-structure layer is embedded between the mesa portion and the base portion.

8. The semiconductor light-emitting device according to claim 1, wherein the optical micro-structure layer comprises a plurality of discontinuous optical micro-structures.

9. The semiconductor light-emitting device according to claim 1, wherein the optical micro-structure layer comprises micro-structures in a continuous manner.

10. The semiconductor light-emitting device according to claim 8, wherein the micro-structures are shaped as bars, dots, islands, columns, cones, pyramids or a combination thereof.

11. The semiconductor light-emitting device according to claim 8, wherein surface number densities of at least a part of the optical micro-structures vary according to different locations.

12. The semiconductor light-emitting device according to claim 8, wherein the optical micro-structures are substantially uniformly distributed.

13. The semiconductor light-emitting device according to claim 1, wherein the optical micro-structure layer is a distributed Bragg reflector layer.

14. The semiconductor light-emitting device according to claim 1, wherein the optical micro-structure layer comprises a phosphor.

15. A method for manufacturing a semiconductor light-emitting device, comprising:
providing a substrate;
forming a first type doped semiconductor material on the substrate to form a base portion of a first type doped semiconductor;
forming a patterned growth barrier layer on the base portion of the first type doped semiconductor, the patterned growth barrier layer exposing a first portion of the first type doped semiconductor and covering a second portion of the first type doped semiconductor;
proceeding to grow the first type doped semiconductor material on the first portion to form a mesa portion of the first type doped semiconductor;
forming a light-emitting layer on the mesa portion of the first type doped semiconductor; and
forming a second type doped semiconductor layer on the light-emitting layer.

16. The method for manufacturing the semiconductor light-emitting device according to claim 15, further comprising:
forming an optical micro-structure layer on the first portion after forming the patterned growth barrier layer and before proceeding to grow the first type doped semiconductor material on the first portion.

17. The method for manufacturing the semiconductor light-emitting device according to claim 16, wherein proceeding to form the first type doped semiconductor material on the first portion comprising: causing the first type doped semiconductor material to cover the optical micro-structure layer.

18. The method for manufacturing the semiconductor light-emitting device according to claim 15, further comprising:
removing the patterned growth barrier layer after forming the second type doped semiconductor layer on the light-emitting layer; and
forming a first electrode and a second electrode respectively on the second portion and the second type doped semiconductor layer.
